(19) United States
(12) Patent Application Publication
(10) Pub. No.: US 2010/0147219 A1
(43) Pub. Date: Jun. 17, 2010

(54) HIGH TEMPERATURE AND HIGH VOLTAGE ELECTRODE ASSEMBLY DESIGN

(76) Inventors: Jui Hai Hsieh, Hsinchu City (TW); David DeLong, Austin, TX (US)

Correspondence Address: Zarian Midgley & Johnson PLLC, University Plaza, 960 Broadway Ave., Suite 250, Boise, ID, 83706, US

(21) Appl. No.: 12/635,482

(22) Filed: Dec. 10, 2009

Related U.S. Application Data
(60) Provisional application No. 61/122,066, filed on Dec. 12, 2008.
(60) Provisional application No. 61/164,552, filed on Mar. 30, 2009.

(51) Int. Cl. C23C 16/00; B23P 6/00

(52) U.S. Cl. 118/723 R; 29/402.01

(57) ABSTRACT

A chemical vapor deposition apparatus is disclosed. The chemical vapor deposition apparatus comprises a chamber having a base plate, a chamber wall, a gas inlet and a gas outlet. The base plate has holes therethrough. A plurality of electrodes extend through the holes of the base plate. The plurality of electrodes are capable of being attached to a power source. At least two of the plurality of electrodes are capable of being electrically coupled to a silicon rod positioned in the chamber. An electrical isolation bushing can be positioned between each of the plurality of electrodes and the base plate. The electrical isolation bushing comprises a sleeve portion surrounding a portion of the electrodes that extends through the base plate and a collar portion surrounding the holes at a surface of the base plate. In some instances, the collar portion can comprise a different material than the sleeve portion. In some instances, an isolation layer can be employed in addition to the isolation bushing, the isolation layer surrounding the holes at the surface of the base plate. In some instances, the collar portion and the sleeve portion are both ceramic.

### RELATED APPLICATIONS

The present application claims benefit of U.S. Provisional Patent Application Nos. 61/122,066, filed on Dec. 12, 2008, and 61/164,552, filed on Mar. 30, 2009, both of which applications are incorporated herein by reference in their entirety. The present application further claims benefit of U.S. patent application Ser. No. 12/607,860, filed on Oct. 28, 2009, which claims benefit of U.S. Provisional Patent Application No. 61/109,137, filed on Oct. 28, 2008, both of which applications are incorporated herein by reference in their entirety.

### BACKGROUND

1. Field of the Disclosure

The present disclosure relates generally to electrodes, such as electrodes employed in CVD reactors.

2. Description of the Related Art

A popular method of manufacturing high purity polycrystalline silicon is through the use of a CVD reactor. FIG. 1 illustrates an example of a CVD reactor employed in such methods, which is known as a “Siemens Reactor”. During the manufacture of silicon in CVD reactors, a CVD reaction takes place on silicon rods which are heated to high temperatures, such as, for example, temperatures of about 1100° C. or more. The heat up is accomplished via electrical power introduced into the chamber through vertical stand electrodes 4, which conduct electrical current and heat up the silicon rods 2. The rods are exposed to a reaction gas which is typically a mixture of hydrogen and a silicon source gas. A common silicon source for this application is Trichlorosilane (TCS). Other well known source gases include monosilane and triethoxysilane.

Vertical stand electrodes 4 can be designed to conduct high levels of power into the CVD reactor chamber. These electrodes are often made of oxygen-free copper. Their complex design accommodates several functions, including conductance of high electrical current, acceptance of high voltage contacts, as well as adequate cooling water flow. The cooling water can have any suitable flow rate that maintains a low enough electrode temperature to avoid substantially melting an insulation material 6, typically polytetrafluoroethylene (“PTFE”). The insulation material is positioned on the outside of the electrode, as shown in FIG. 2. The insulation material works as electrical isolation, as well as a vacuum seal and/or high pressure seal. As shown in FIGS. 1 and 3, the electrode can use a graphite adapter 8 on the top of electrode to link the silicon rod 2 and copper electrode 4.

The top of the electrode 4 is exposed to the working area of the chamber, including corrosive chemicals and high temperatures. Further, it can easily be damaged by either surface micro arcing or physical damage during the harvest of polysilicon. FIGS. 2 and 3 show areas 10 proximate the top of electrode 4 that can often have increased risk of failure due to surface micro arcing.

With the design of FIG. 2, when damage occurs to the electrode top, the entire electrode is replaced. The electrode replacement process consumes a 24-hour period in the best case. Replacement of the electrode has a ripple effect to the cost of operation, as well as the production revenue. The electrode is an expensive part and is labor intensive to replace, while the unscheduled down time causes loss of production time and unrecoverable loss of revenue.

A second disadvantage of the design of FIG. 2 is related to the addition of isolation materials below the electrode top. In the industry, it is desirable to attain high power through the electrodes up to about 15 KV or more, while the design illustrated in FIG. 2 may not be suitable for operating in a voltage range above about 7 KV due to the increased potential for electrical arcing, as well as higher electrode temperatures.

In addition, because the isolation material will be exposed to very high temperatures, the use of fragile materials such as quartz or ceramic can be desirable. Because the isolation material can be fragile, ease of replacement would be an advantage.

The present disclosure is directed to overcoming, or at least reducing the effects of, one or more of the issues set forth above.

### SUMMARY

The present disclosure includes an electrode assembly design for use in polycrystalline silicon CVD reactors that can provide one or more of the following advantages: improved throughput by allowing for a substantially higher electrical voltage to be delivered to the chamber; a decrease in the time required to heat up the reaction chamber to process temperatures, which can be, for example, about 1100° C. or greater; significantly improved tolerance to higher temperatures and better electrical isolation properties for the electrode assembly, which can allow the electrode to operate at higher voltages, such as, for example, in the 8 KV to 45 KV range; or reduced maintenance time and/or operation costs by allowing for replacement or repair of the electrode top without removing the electrode body from the base plate. Currently with the existing electrode design this maintenance activity can take 24 hours or more. Using certain electrode designs of the present disclosure, it may be possible to significantly reduce repair or replacement time. For example, in some cases, repair or replacement time may be less than about 1 hour.

An embodiment of the present disclosure is directed to a chemical vapor deposition apparatus. The chemical vapor deposition apparatus comprises a chamber having a base plate, a chamber wall, a gas inlet and a gas outlet. The base plate has holes therethrough. A plurality of electrodes extend through the holes of the base plate. The plurality of electrodes are capable of being attached to a power source. At least two of the plurality of electrodes are capable of being electrically coupled to a silicon rod positioned in the chamber. An electrical isolation bushing can be positioned between each of the plurality of electrodes and the base plate, the electrical isolation bushing comprising a sleeve portion surrounding a portion of the electrodes that extends through the base plate and a collar portion surrounding the holes at a surface of the base plate. The collar portion comprises a different material than the sleeve portion.

Another embodiment of the present disclosure is directed to a chemical vapor deposition apparatus. The chemical vapor deposition apparatus comprises a chamber having a base plate, a chamber wall, a gas inlet and a gas outlet. The base plate has holes therethrough. A plurality of electrodes extend through the holes of the base plate. The plurality of electrodes are capable of being attached to a power source. At least two of the plurality of electrodes are capable of being electrically coupled to a silicon rod positioned in the chamber. An electrical isolation bushing can be positioned between each of the plurality of electrodes and the base plate. An isolation layer in addition to the isolation bushing can surround the holes at the surface of the base plate.

Another embodiment of the present disclosure is directed to a vertical stand electrode assembly. The vertical stand electrode assembly comprises an electrode body and an electrode ring attached to the body.

Another embodiment of the present disclosure is directed to a method of repairing an electrode in a chemical vapor deposition apparatus. The electrode comprises an electrode body positioned in the chemical vapor deposition apparatus and an electrode ring removably attached to the body. The method comprises removing the electrode ring from the electrode body; and attaching a new electrode ring to the electrode body, wherein the electrode body remains positioned in the chemical vapor deposition apparatus during at least a portion of the time that the electrode cap is removed.

Another embodiment of the present disclosure is directed to a vertical stand electrode assembly. The vertical stand electrode assembly comprises an electrode body. The electrode body comprises a shoulder capable of supporting the electrode when the electrode is positioned in a base plate of a chemical vapor deposition reactor. The electrode top portion is configured to be removably attached to the body.

Another embodiment of the present disclosure is directed to a chemical vapor deposition apparatus. The chemical vapor deposition apparatus comprises a chamber having a base plate, a chamber wall, a gas inlet and a gas outlet. The base plate has holes therethrough. A plurality of electrodes extend through the holes of the base plate. The plurality of electrodes are capable of being attached to a power source. At least two of the plurality of electrodes are capable of being electrically coupled to a silicon rod positioned in the chamber. An electrical isolation bushing can be positioned between each of the plurality of electrodes and the base plate, the electrical isolation bushing comprising a sleeve portion surrounding a portion of the electrodes that extends through the base plate and a collar portion surrounding the holes at a surface of the base plate. The collar portion is a ceramic material.

### BRIEF DESCRIPTION OF THE DRAWINGS

FIG. 1 illustrates a schematic drawing of a CVD apparatus.

FIGS. 2 and 3 illustrate CVD electrodes.

FIGS. 4 and 5 illustrate electrodes, according to an embodiment of the present disclosure.

FIG. 6 illustrates an isolation layer positioned between a base plate and a collar portion, according to an embodiment of the present disclosure.

FIG. 7 illustrates a collar portion positioned between a base plate and an isolation layer, according to an embodiment of the present disclosure.

FIG. 8 illustrates an electrode in which the isolation layer is a replaceable ring, according to an embodiment of the present disclosure.

FIG. 9 illustrates an electrode employed with a base plate liner, according to an embodiment of the present disclosure.

FIG. 10 illustrates a base plate liner, according to an embodiment of the present disclosure.

FIG. 11A illustrates a base plate liner with a surface isolation coating, according to an embodiment of the present disclosure.

FIG. 11B illustrates a base plate liner with a surface isolation coating and an electrical isolation layer, according to an embodiment of the present disclosure.

FIG. 12 illustrates an electrode employed with a base plate liner, according to another embodiment of the present disclosure.

FIGS. 13-15 illustrate electrodes having an electrode ring, according to another embodiment of the present disclosure.

FIGS. 16-19 illustrate still other electrodes, according to various embodiments of the present disclosure.

FIG. 20 illustrates a schematic drawing of a CVD apparatus, according to an embodiment of the present disclosure.

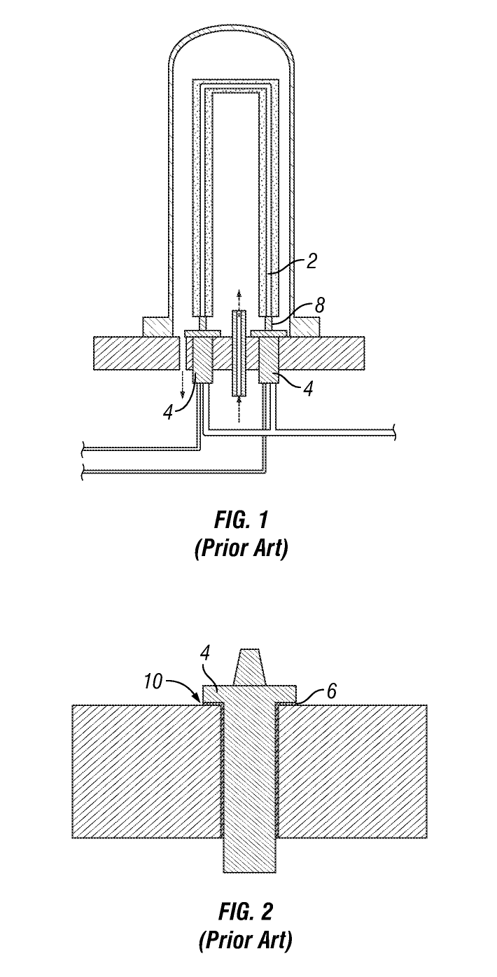

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the spirit and scope of the invention as defined by the appended claims.

### DETAILED DESCRIPTION

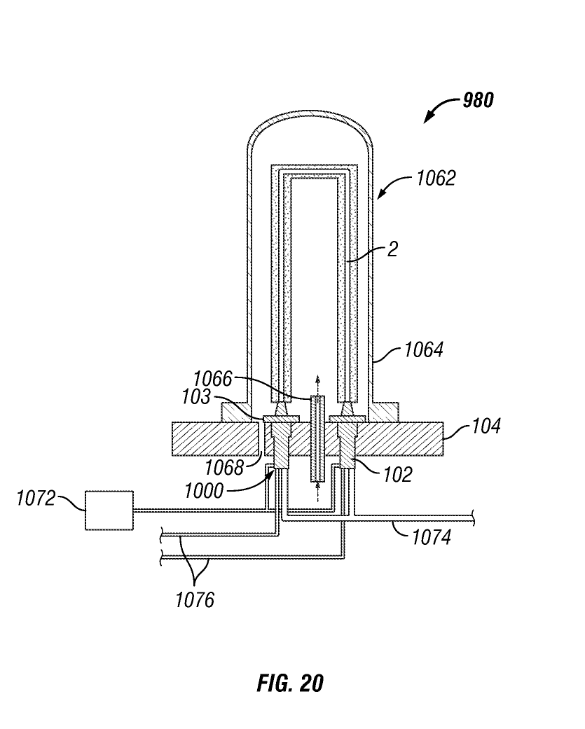

FIG. 4 illustrates an electrode 100, according to an embodiment of the present disclosure. The electrode 100 includes an electrode body 102 and a top electrode portion 103. The electrode 100 may be positioned through holes 104a in a base plate 104 of a chemical vapor deposition apparatus, such as the apparatus shown in FIG. 20 and described in greater detail below. Base plate 104 further includes an upper surface 104b and a bottom surface 104c.

An electrical isolation bushing 106 is positioned between the electrode 100 and the base plate 104. The electrical isolation bushing 106 includes a sleeve portion 108 surrounding a portion of the electrode body 102 that extends through the base plate 104. The electrical isolation bushing 106 also includes a collar portion 110 surrounding the holes 104a at the upper surface 104b of the base plate 104. In an embodiment, the collar portion 110 can be separable from the sleeve portion 108. The collar portion 110 can comprise a different material than the sleeve portion 108, where the different material can provide for reduced microarcing relative to the material used for sleeve portion 108. For example, the collar portion 110 can be a ceramic or quartz material.

In an embodiment, the collar portion 110 extends into the holes 104a from the upper surface 104b of the base plate 104 so as to line a portion of the holes 104a. The use of ceramic material in place of, for example, PTFE for the collar portion 110 can reduce surface micro arcing near the top electrode portion 103. The collar portion 110 can be any suitable thickness that will provide the desired electrical isolation.

The sleeve portion 108 of the isolation bushing 106 can be a polymer insulator. Any suitable polymer material that provides the desired insulating properties and that can withstand the high temperature processing conditions to which the electrode will be subjected can be employed. An example of a suitable material is polytetrafluoroethylene (“PTFE”).

In an embodiment, the sleeve portion 108 extends between the collar portion 110 and the electrode body 102, as illustrated in FIG. 4. In yet another embodiment, the sleeve portion 108 that extends between the collar portion 110 and electrode body can be omitted, so that the upper portion of the bushing 106 is made completely of ceramic material.

FIG. 5 illustrates an electrode 200, according to an embodiment of the present disclosure. Electrode 200 is similar to the electrode 100 of FIG. 4, as described above, except that electrode 200 includes an isolation layer 212 positioned between the electrode top portion 103 and the collar portion 110 of bushing 106; and the sleeve portion 108 and the collar portion 110 are both made of the same material, so that the electrical isolation bushing 106 can be a single integral part, if desired.

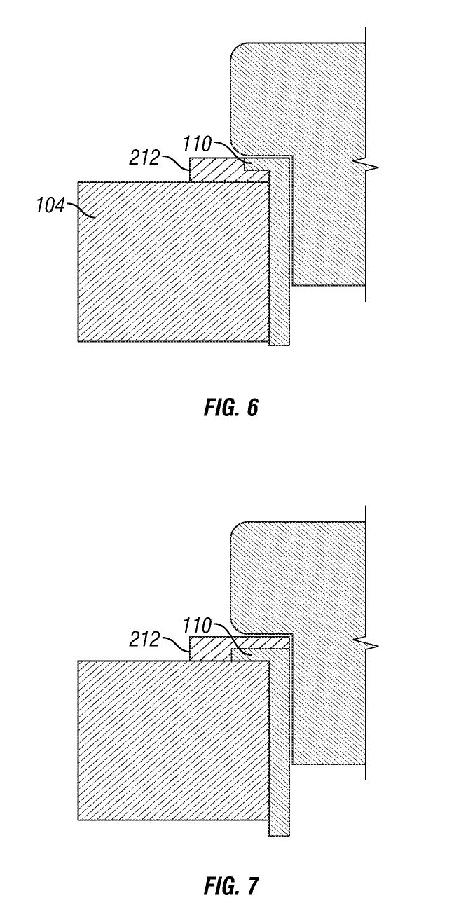

Thus, isolation layer 212 can be used in addition to the collar portion 110 of bushing 106. This can provide for added electrical insulation between the electrode top portion 103 and the base plate 104. The thickness and width of the isolation layer 212 can vary depending on the voltage levels employed, with thicker and wider dimensions being employed for high voltage applications. In some instances, the width of isolation layer 212 can be increased to extend beyond the end of the electrode top portion, as shown, for example, in the embodiments of FIGS. 6 and 7, discussed below.

In an embodiment, the bushing 106 can be a polymer and the isolation layer 212 can comprise at least one material chosen from quartz or ceramic. In an embodiment, the polymer used for the bushing can be at least one material chosen from polytetrafluoroethylene and perfluoroalkoxy plastic.

The arrangement of the isolation layer 212 and collar portion 110 of bushing 106 can vary. For example, as illustrated in FIG. 6, the isolation layer 212 can be positioned between the base plate 104 and the collar portion 110. In another embodiment, as illustrated in FIG. 7, the collar portion 110 can be positioned between the base plate 104 and the isolation layer 212. Yet other arrangements would be readily apparent to one of ordinary skill in the art.

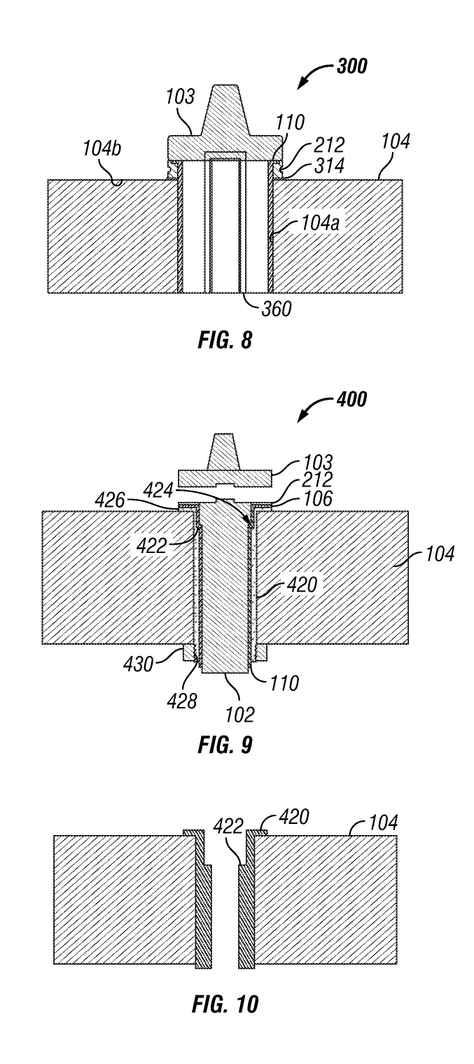

The isolation layers 212 can be separate from the collar portion 110, thereby allowing for easy replacement in the event the isolation layer 212 becomes damaged, without having to replace the entire bushing 106. In yet another embodiment, as illustrated by electrode 300 shown in FIG. 8, the isolation layer 212 is a replaceable ring that is positioned between a polymer gasket 314 and the collar 110 of bushing 106. The polymer gasket 314 surrounds the hole 104a proximate the upper surface 104b of base plate 104. The polymer gasket 314 can be made of any suitable polymer that can withstand the high temperature processing conditions, such as PTFE or perfluoroalkoxy plastic. By sandwiching the isolation layer 212 between the polymer collar 110 and polymer gasket 314, a seal can be formed on either side of the isolation layer 212, thereby sealing the process chamber to reduce gas leaking from the chamber and protecting the electrode body 102 from the corrosive gases in the processing chamber.

FIG. 9 illustrates an electrode 400, according to an embodiment of the present disclosure. Electrode 400 includes a top electrode portion 103 that is removable from the electrode body 102. Electrode 400 can be employed with a base plate liner 420, according to an embodiment of the present disclosure. The base plate liner 420 can include a shoulder 422, as illustrated more clearly in FIG. 10. Electrode 400 comprises a shoulder 424 in the electrode body 102 that corresponds to the shoulder 422 in the base plate liner 420. The base plate liner 420 can be positioned in the base plate 104 of a CVD apparatus. By employing this arrangement, the electrode body 102 can be supported by the base plate liner 420 when the electrode top portion 103 is removed.

The base plate liner 420 can be made of any suitable material that can withstand high processing temperatures and still provide structural integrity. Examples of suitable base plate liner materials include electrical insulating materials, such as quartz or ceramic, and metals, such as stainless steel, nickel alloy, nickel plated steel, nickel plated stainless steel, silver plated steel, and silver plated stainless steel.

The base plate liner 420 can be held in position in the base plate 104 using any desired technique. For example, the base plate liner 420 can comprise a lip 426 and a threaded region 428 capable of attaching to a nut 430. The base plate liner 420 can be held in place on the base plate 104 between the lip 426 and the nut 430, as shown in the embodiment of FIG. 9. Other examples of techniques for holding the base plate liner in place include a friction fit between the base plate liner 420 and base plate 104, or the use of bolts or other fasteners.

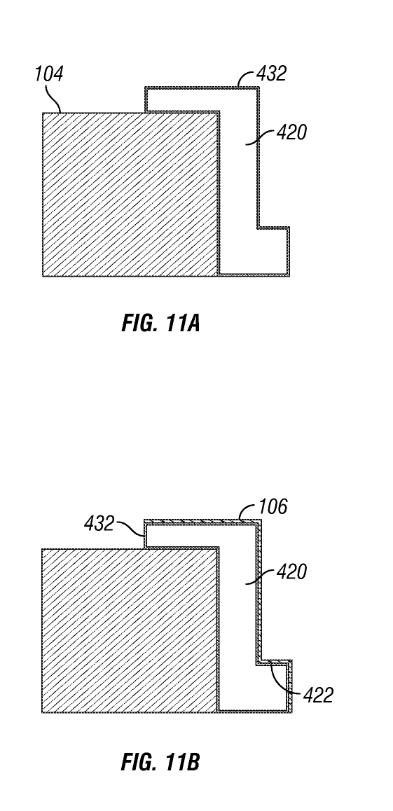

In embodiments where the base plate liner 420 is metal, a surface isolation coating 432 can be formed on the base plate liner 420, as illustrated in FIG. 11A. The surface isolation coating 432 can comprise an insulating material such as, for example, ceramic, quartz, PTFE, or PFA. The surface isolation coating 432 provides electrical isolation between the base plate 104 and the base plate liner 420, while the base plate liner 420 comprising metal can provide mechanical strength for supporting the electrode 400. In this manner, the base plate liner 420 made of metal in combination with the surface isolation coating 432 can provide for improved reliability when compared to, for example, a quartz or ceramic liner, which may have a tendency to break more easily during installation or operation.

As illustrated in FIGS. 9 and 11B, electrical isolation bushing 106 can be employed between the base plate liner 420 and the electrode 400. The electrical isolation bushing 106 is similar to the bushing of the embodiment of FIG. 5, except that it includes a shoulder corresponding to shoulder 422. The electrical isolation bushing 106 can be formed in addition to the surface isolation coating 432.

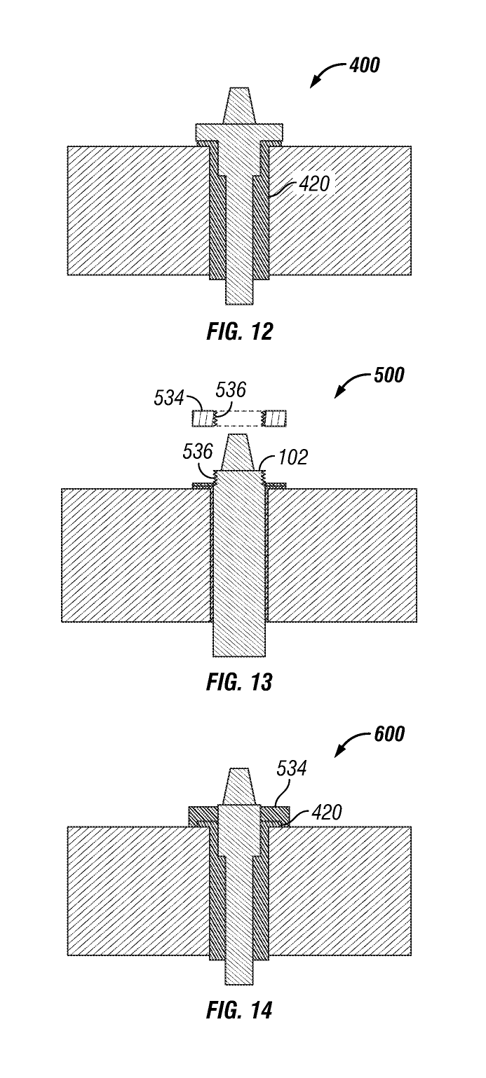

In embodiments where the base plate liner 420 itself provides sufficient electrical isolation between the electrode 400 and the base plate 104, the electrical isolation layer and/or surface isolation coating 432 can optionally be omitted. FIG. 12 illustrates such an embodiment, where the base plate liner 420 is made of, for example, quartz or ceramic, thereby providing sufficient electrical isolation between the electrode 400 and the base plate 104.

The top electrode portion 103 can be designed to cover the surface of the electrode body 102 that would otherwise be exposed to the deposition process inside a CVD chamber. As discussed above, the surface of the electrodes of the present disclosure may be damaged during chemical vapor deposition and/or the harvesting of silicon from the CVD apparatus. The ability to remove the top electrode portion 103 of the electrodes can be advantageous because this allows the top portion 103 to be replaced without having to replace to entire electrode. In addition, the ability to remove the top portion 103 allows for easy removal and/or replacement of either or both of the isolation layer 212 and polymer gasket 314.

The top portion 103 can be made of any suitable electrically conductive material. Examples of such material include oxygen free copper, silver alloys, and copper alloys. The top portion 103 can be coated with a metal coating material, which can be, for example, silver, silver alloys, nickel, nickel alloys, tin, tin alloys, gold and gold alloys. For example, the top portion 103 can comprise oxygen free copper coated with silver, or any other suitable metal coatings. Such coatings for the top portion 103 are disclosed in co-pending U.S. patent application Ser. No. 12/607,860, filed on Oct. 28, 2009, the disclosure of which is hereby incorporated by reference in its entirety.

FIG. 13 illustrates an electrode 500, according to yet another embodiment of the present disclosure. Electrode 500 comprises an electrode body 102 and an electrode top portion that is in the form of an electrode ring 534 removably attached to the electrode body 102. The electrode body 102 can be positioned through the base plate, with a top of the electrode body 102 and the electrode ring 534 being positioned inside the chemical vapor deposition chamber. The electrode ring 534 can attach to the electrode body 102 in any suitable fashion. For example, both the electrode ring 534 and the electrode body 102 can have matching threads 536, which allow the electrode ring 534 to screw onto electrode body 102. This allows the ability to replace the electrode ring 534 without having to replace to entire electrode 500. In addition, it can allow for easy removal and/or replacement of either or both of the voltage isolation layer 212 and polymer gasket 314. For example, the isolation layer 212 and polymer gasket 314 can be replaced without having to remove the electrode body 102 from the base plate 104.

The electrode ring 534 can comprises any suitable type of material, such as metal or an electrical isolation material, such as quartz, ceramic or a polymer material. Suitable metals can include any of the metals disclosed herein for making the electrodes of the present disclosure. Where the electrode ring 534 is an electrical isolation material, it may be desirable to omit using the voltage isolation layer 212 and/or polymer gasket 314.

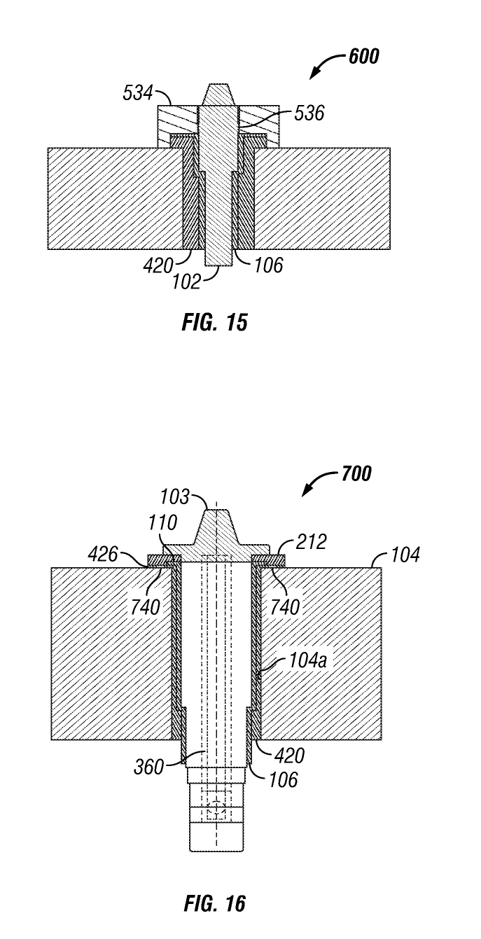

FIGS. 14 and 15 illustrate electrodes 600 comprising an electrode ring 534 that comprises an electrical isolation material, according to an embodiment of the present disclosure. In this embodiment, the electrode ring 534 is designed to cover the end region of the base plate liner 420. If an electrical isolation bushing 106, voltage isolation layer 212 and/or polymer gasket 314 are employed (none of which are illustrated in FIG. 14), the ends of these can also be covered by electrode ring 534. This can potentially allow for ultra high voltage applications with reduced arcing and/or leakage. The base plate liner 420 can include any of the materials described herein for use as base plate liners, including metals, coated metals, and isolation materials.

The electrode ring 534 of the embodiments of FIGS. 14 and 15 can be made of any suitable isolation material, such as ceramic or quartz. The ring 534 can be attached to the electrode body 102 in any suitable manner, such as by using bolts, screws, or an adhesive. As illustrated in FIG. 15, the electrode ring 534 can be attached so as to be easily removable from the electrode body 102. For example, both the electrode ring 534 and the electrode body 102 can have matching threads 536, similarly as described in the embodiment of FIG. 13, thereby allowing the electrode ring 534 to screw on and off of the electrode body 102. Any other suitable method for attaching the electrode ring 534 to the electrode body 102 can also be employed.

FIG. 16 illustrates an electrode 700, according to an embodiment of the present disclosure. The electrode 700 extends through base plate 104. A base plate liner 420 and electrical isolation bushing 106 are positioned between the electrode 700 and the base plate 104. A voltage isolation layer 212 is positioned so as to surround the hole 104a proximate the surface of the base plate 104 adjacent to the collar portion 110 of the electrical isolation bushing 106 and the lip 426 of the base plate liner 420. An o-ring seal 740 can be positioned in order to provide a more reliable seal between the base plate liner 420 and the base plate 104.

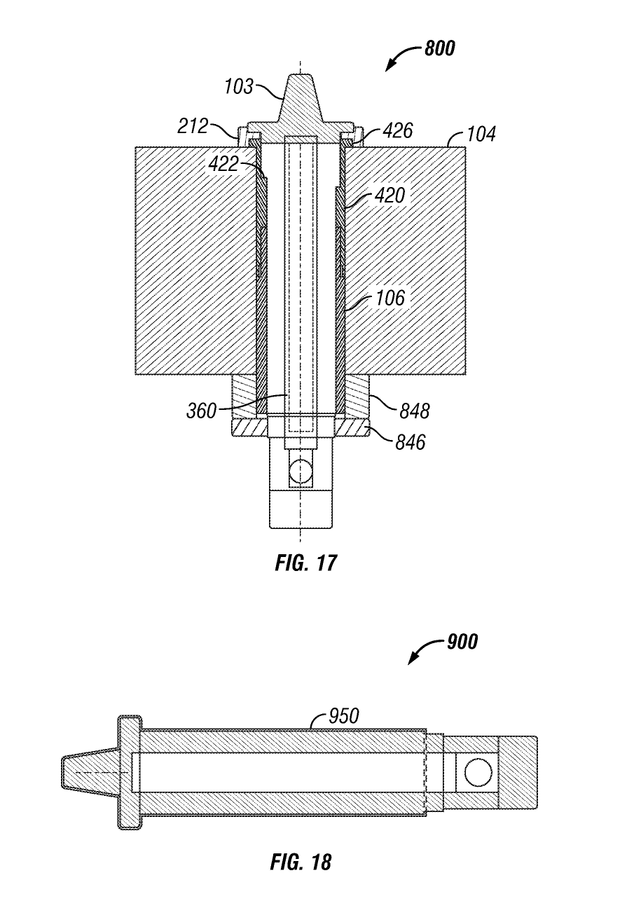

FIG. 17 illustrates an electrode 800, according to an embodiment of the present disclosure. The electrode 800 extends through base plate 104. A base plate liner 420 extends only a first portion of the way through base plate 104. The base plate liner 420 can comprise an isolation material or metal, such as stainless steel or any of the other metals disclosed herein for base plate liners. The base plate liner 420 can include a surface isolation coating (not shown), similar to the surface isolation coating 432 discussed above with respect to FIG. 11A. The surface isolation coating can comprise any of the materials described above for use as a surface isolation coating, including, for example, PTFE. Base plate liner 420 is configured with a shoulder 422 so as to support the weight of the electrode 800.

An electrical isolation bushing 106 is positioned between the electrode 800 and the base plate 104. The electrical isolation bushing 106 can comprise any material disclosed herein for use as electrical isolation bushing materials, include, for example, PTFE or PFA. The electrical isolation bushing 106 extends a second portion of the way through base plate 104, from the base plate liner 420 on through the remainder of the base plate 104. A portion of the electrical isolation bushing 106 can extend alongside the base plate liner 420, which in some instances may be employed to provide additional isolation to block the voltage between the electrode body 102 and the base plate 104.

An isolation layer 212 can be positioned so as to surround the hole 104a proximate the surface of the base plate 104. For example, isolation layer 212 can be adjacent to, and covering the end of, the lip 426 of the base plate liner 420 and a portion of the outer circumference of top electrode portion 103.

The electrical isolation bushing 106 and/or electrode body 102 can also be supported relative to the base plate 104 by a flange 846 and isolation washer 848, as illustrated in FIG. 17, according to an embodiment of the present disclosure. The flange can be, for example, a stainless steel hex flange. The isolation washer can be, for example, a PTFE washer, which can act to seal off the space between the flange 846 and the base plate 104.

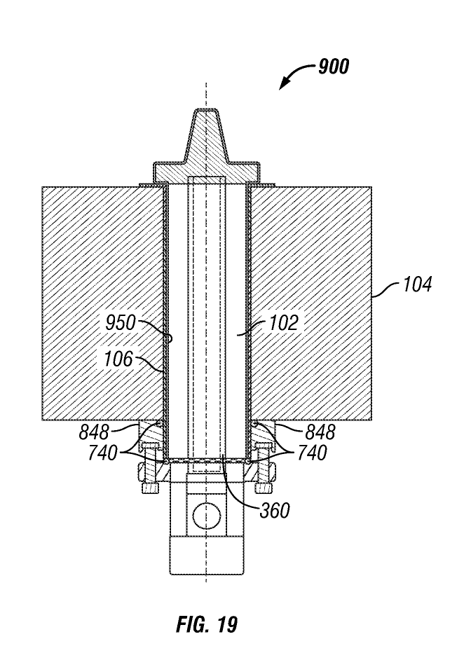

FIGS. 18 and 19 illustrate an electrode 900, according to another embodiment of the present disclosure. Electrode 900 can be similar to any of the other electrodes described herein, except that the surface of electrode 900 includes an extended coating of electroplated silver 950. The coating 950 is employed to reduce or eliminate the reaction of the copper electrode with any process gases from the chamber, as well as associated contamination leaching into the process chamber.

The coating can allow the sealing mechanism to be employed near the bottom of the electrode, as opposed to near the top of the electrode. The reason for employing the seal near the bottom of the electrode is that the isolation bushing material, such as PTFE or other polymer, has the capability and flexibility to provide a reliable seal. With the change of insulator material from polymer to ceramic or quartz near the top of the electrode, the rigid material, such as ceramic, will be very difficult to effectively seal between the base plate and the electrode.

FIG. 19 illustrates the electrode 900 with seals 740 near the bottom of the electrode, according to an embodiment of the disclosure. Any suitable seals can be employed. For example, o-ring seals can be employed between the base plate 104, the electrical isolation bushing 106, and the isolation washer 848, as well as between the electrode body 102 and the electrical isolation bushing 106, as shown in FIG. 19. The seals can provide for more reliable sealing of the CVD chamber, which may be operated at relatively high pressures and have variance in tolerances between the components.

The addition of multiple seals 740, such as the two illustrated at the bottom of the electrode 900, can be implemented in an electrode comprising the collar portion 110, as described previously with respect to, for example, FIG. 4 above, or in any of the other embodiments of the present disclosure. In an embodiment, the seals 740, the collar portion 110, the electrical isolation bushing 106, the isolation washer 848 and the coating of electroplated silver 950 can be implemented together to provide for relatively high voltage isolation and/or higher process temperatures near the top of the electrodes of the present disclosure, and/or while preserving the pressure sealing integrity of the CVD chambers, which may help to reduce introduction of contamination into the chambers in some instances. The seals 740 can also be employed with any of the other embodiments disclosed herein.

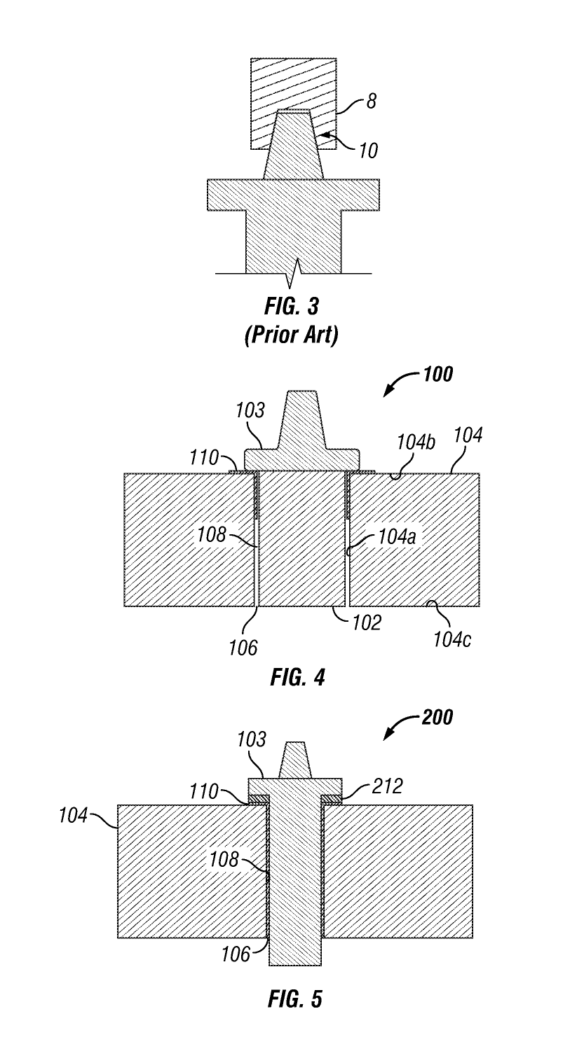

Any of the above described electrodes of the present disclosure can be employed in any suitable chemical vapor deposition apparatus. An example of a suitable chemical vapor deposition apparatus 980 is illustrated in FIG. 20. The CVD apparatus 980 includes a chamber 1062 comprising a base plate 104, a chamber wall 1064, a gas inlet 1066 and a gas outlet 1068. A plurality of electrodes 1000 (which can include any of the electrodes of the present disclosure) each comprise an electrode body 102 and a top electrode portion 103 removably attached to the body 102. The electrode body 102 can be positioned through the base plate 104. The top electrode portion 103 can be positioned inside the chamber 1062. A silicon rod 2 can be electrically coupled to at least two electrodes 1000 in the chamber 1062. While only a single silicon rod 2 is illustrated, the chamber 1062 can include a plurality of silicon rods 2, as is well known in the art. An adapter 8 (FIG. 3) can be positioned between the silicon rod 2 and each electrode 1000. A power source 1072 can be attached to the plurality of electrodes, as is also well known in the art.

The electrodes of the present disclosure can be liquid cooled electrodes. FIG. 20 illustrates coolant conduits 1074 and 1076, which can be employed for flowing a coolant, such as water, to and from the electrodes 1000. In an embodiment, the electrodes can be designed to have internal coolant flow paths 360, as schematically illustrated in FIGS. 8, 16, 17, 19. Cooling the electrodes in such a manner is well known in the art to provide the desired cooling. Examples of electrodes designed with coolant flow configurations are also taught in U.S. patent application Ser. No. 12/270,981, which was filed by the inventor of the present disclosure on Nov. 14, 2008, the disclosure of which is hereby incorporated by reference in its entirety.

The present disclosure is also directed to a method of repairing the above described electrodes in a chemical vapor deposition apparatus 980. The method comprises removing the top electrode portion 103 from the electrode body 102. A new top electrode portion 103 can then be attached to the electrode body 102 to replace the damaged top electrode portion 103. If the electrode includes an isolation layer 212 positioned under the top electrode portion 103, the isolation layer 212 can be replaced with a new isolation layer 212 after removing the top electrode portion 103. The electrode body 102 can remain positioned in the chemical vapor deposition apparatus 980 during at least a portion of the time that the top electrode portion 103 is removed from the body 102.

In order to conduct high levels of power into the CVD reactor chamber, the electrodes of the present disclosure can be made of any suitable conductive material. For example, the conductive material can be a material that can provide an electrical conductivity of about 100% IACS or greater, and that can withstand the operating conditions to which the electrode will be subjected, which may include relatively high operating temperatures and stresses due to high pressure coolant flows. In an embodiment, the high conductivity metal can comprise at least 99% pure copper by weight, such as 99.95% pure copper. In an embodiment, the conductive material can be chosen from metals having a low oxygen content, such as a metal comprising an oxygen content of 0.05% or less, such as an oxygen content ranging from about 0 to about 0.035%, or about 0 to about 0.001%. Examples of suitable low oxygen content metals include low oxygen content copper, such as substantially oxygen free copper (“OFC”) or an alloy thereof. For purposes of this specification, “substantially oxygen free copper” is defined to be 99.95% pure copper having 0.001% or less of oxygen content with the minimum conductivity of 100% IACS. Thus, such substantially oxygen free copper has the benefit of being highly conductive. In another embodiment, electrolytic tough pitch copper (ETP Cu) may be employed, which can have an oxygen content ranging from about 0.02% to about 0.035% by weight (200-350 ppm).

Although various embodiments have been shown and described, the disclosure is not so limited and will be understood to include all such modifications and variations as would be apparent to one of ordinary skill in the art.

What is claimed is:

1. A chemical vapor deposition apparatus, comprising:
a chamber having a base plate, a chamber wall, a gas inlet and a gas outlet, the base plate having holes therethrough;
a plurality of electrodes extending through the holes of the base plate, the plurality of electrodes being capable of being attached to a power source, and at least two of the plurality of electrodes being capable of being electrically coupled to a silicon rod positioned in the chamber; and
an electrical isolation bushing positioned between each of the plurality of electrodes and the base plate, the electrical isolation bushing comprising a sleeve portion surrounding a portion of the electrodes that extends through the base plate and a collar portion surrounding the holes at a surface of the base plate, the collar portion comprising a different material than the sleeve portion.

2. The chemical vapor deposition apparatus of claim 1, wherein the collar portion extends into the holes from the surface of the base plate so as to line a portion of the holes.

3. The chemical vapor deposition apparatus of claim 2, wherein the sleeve portion of the isolation bushing is a polymer insulator and the collar portion is a ceramic material.

4. The chemical vapor deposition apparatus of claim 3, wherein the polymer insulator is polytetrafluoroethylene.

5. The chemical vapor deposition apparatus of claim 3, wherein the sleeve portion extends between the ceramic collar portion and the electrode.

6. The chemical vapor deposition apparatus of claim 1, wherein each of the plurality of electrodes comprises a coating of electroplated silver.

7. The chemical vapor deposition apparatus of claim 6, wherein the coating of electroplated silver covers the portion of the electrodes extending through the base plate.

8. The chemical vapor deposition apparatus of claim 6, further comprising a washer attached to an end of each of the plurality of electrodes, and further wherein a first seal is positioned between the washer, the base plate and the electrical isolation bushing; and a second seal is positioned between each electrode and the electrical isolation bushing.

9. A chemical vapor deposition apparatus, comprising:
a chamber having a base plate, a chamber wall, a gas inlet and a gas outlet, the base plate having holes therethrough;
a plurality of electrodes extending through the holes of the base plate, the plurality of electrodes being capable of being attached to a power source, and at least two of the plurality of electrodes being capable of being electrically coupled to a silicon rod positioned in the chamber;
an electrical isolation bushing positioned between each of the plurality of electrodes and the base plate; and
an isolation layer in addition to the isolation bushing, the isolation layer surrounding the holes at the surface of the base plate.

10. The chemical vapor deposition apparatus of claim 9, wherein the electrical isolation bushing comprises a sleeve portion surrounding a portion of each of the electrodes that extend through the base plate and a collar portion surrounding the holes at the surface of the base plate.

11. The chemical vapor deposition apparatus of claim 10, wherein the bushing is a polymer and the isolation layer comprises a material chosen from quartz and ceramic.

12. The chemical vapor deposition apparatus of claim 10, wherein the bushing is chosen from polytetrafluoroethylene and perfluoroalkoxy plastic.

13. The chemical vapor deposition apparatus of claim 10, wherein the collar portion of the bushing is positioned between the base plate and the isolation layer.

14. The chemical vapor deposition apparatus of claim 10, wherein the isolation layer is positioned between the base plate and the collar portion of the bushing.

15. The chemical vapor deposition apparatus of claim 9, wherein the isolation layer is a replaceable ring.

16. The chemical vapor deposition apparatus of claim 15, further comprising a polymer gasket surrounding the holes and positioned between the base plate and the replaceable ring.

17. The chemical vapor deposition apparatus of claim 9, further comprising base plate liners positioned in the holes of the base plate, the base plate liners each comprising a first shoulder and the electrodes each comprising corresponding second shoulders, the first and second shoulders configured so that the base plate liners are capable of supporting the plurality of electrodes.

18. The chemical vapor deposition apparatus of claim 17, wherein the base plate liners are metal.

19. The chemical vapor deposition apparatus of claim 18, wherein the base plate liners are coated with a surface isolation coating.

20. The chemical vapor deposition apparatus of claim 19, wherein the base plate liners extend only a first portion of the way through the base plate and the electrical isolation bushing extends a second portion of the way through the base plate.

21. The chemical vapor deposition apparatus of claim 17, wherein the base plate liners are a material chosen from quartz and ceramic.

22. The chemical vapor deposition apparatus of claim 17, wherein the plurality of electrodes each comprise an electrode body and an electrode top portion removably attached to the body, the electrode body positioned through the base plate and the top portion being positioned inside the chamber.

23. The chemical vapor deposition apparatus of claim 22, wherein the isolation layer is a ring that is configured so as to be replaceable when the electrode top portion is removed from the electrode body.

24. The chemical vapor deposition apparatus of claim 17, wherein the plurality of electrodes each comprise an electrode body and an electrode ring removably attached to the body, the electrode body positioned through the base plate and the electrode ring being positioned inside the chamber.

25. The chemical vapor deposition apparatus of claim 24, wherein the electrode ring comprises metal.

26. The chemical vapor deposition apparatus of claim 24, wherein the electrode ring comprises an isolation material.

27. The chemical vapor deposition apparatus of claim 24, wherein the isolation layer is a ring that is configured so as to be replaceable when the electrode ring is removed from the electrode body.

28. The chemical vapor deposition apparatus of claim 1, wherein each of the plurality of electrodes comprises a coating of electroplated silver.

29. The chemical vapor deposition apparatus of claim 1, wherein the silicon rod is attached to the at least two electrodes, and further comprising an adapter positioned between the silicon rod and each electrode.

30. A vertical stand electrode assembly, comprising:
an electrode body; and
an electrode ring attached to the body.

31. The electrode assembly of claim 30, wherein the electrode ring is removable from the electrode body.

32. The electrode assembly of claim 30, wherein the electrode ring comprises metal.

33. The electrode assembly of claim 30, wherein the electrode ring comprises an isolation material.

34. The electrode assembly of claim 30, wherein the electrode comprises a coating of electroplated silver.

35. The electrode assembly of claim 30, wherein the electrode body comprises a shoulder that is configured to support the weight of the electrode.

36. The electrode assembly of claim 30, wherein the electrode is configured to be liquid cooled.

37. A method of repairing an electrode in a chemical vapor deposition apparatus, the electrode comprising an electrode body positioned in the chemical vapor deposition apparatus and an electrode ring removably attached to the body, the method comprising:
removing the electrode ring from the electrode body; and
attaching a new electrode ring to the electrode body, wherein the electrode body remains positioned in the chemical vapor deposition apparatus during at least a portion of the time that the electrode cap is removed.

38. The method of claim 37, further comprising replacing a used isolation layer positioned around the electrode body with a new isolation layer when the electrode ring is removed from the electrode body.

39. A vertical stand electrode assembly, comprising:
an electrode body, the electrode body comprising a shoulder capable of supporting the electrode when the electrode is positioned in a base plate of a chemical vapor deposition reactor; and
an electrode top portion configured to be removably attached to the body.

40. The electrode assembly of claim 39, further comprising a base plate liner comprising a shoulder that corresponds to the shoulder of the electrode body, the base plate liner shoulder configured so that the base plate liners are capable of supporting the electrode.

41. The electrode assembly of claim 39, wherein the removable electrode top portion is an electrode ring.

42. A chemical vapor deposition apparatus, comprising:
a chamber having a base plate, a chamber wall, a gas inlet and a gas outlet, the base plate having holes therethrough;
a plurality of electrodes extending through the holes of the base plate, the plurality of electrodes being capable of being attached to a power source, and at least two of the plurality of electrodes being capable of being electrically coupled to a silicon rod positioned in the chamber; and
an electrical isolation bushing positioned between each of the plurality of electrodes and the base plate, the electrical isolation bushing comprising a sleeve portion surrounding a portion of the electrodes that extends through the base plate and a collar portion surrounding the holes at a surface of the base plate, wherein the collar portion is a ceramic material.

43. The chemical vapor deposition apparatus of claim 42, wherein the sleeve portion of the isolation bushing is a ceramic material.
